(19) United States
(12) Patent Application Publication
(10) Pub. No.: US 2025/0015038 A1
(43) Pub. Date: Jan. 9, 2025

(54) METHOD OF MANUFACTURING SEMICONDUCTOR DEVICES AND CORRESPONDING SEMICONDUCTOR DEVICE

(71) Applicant: STMicroelectronics International N.V., Geneva (CH)

(72) Inventors: Pierangelo MAGNI, Villasanta (IT); Alberto ARRIGONI, Eupilio, Como (IT); Giovanni MISSAGLIA, Burago Molgora (MB) (IT)

(73) Assignee: STMicroelectronics International N.V., Geneva (CH)

(21) Appl. No.: 18/757,887

(22) Filed: Jun. 28, 2024

(30) Foreign Application Priority Data
Jul. 7, 2023 (IT) 102023000014250

(51) Int. Cl. H01L 23/00; H01L 23/31; H01L 23/48; H01L 23/498

(52) U.S. Cl. CPC H01L 24/48; H01L 23/3121; H01L 23/481; H01L 23/49861; H01L 24/08; H01L 24/09; H01L 24/49; H01L 2224/08112; H01L 2224/0913; H01L 2224/48011; H01L 2224/48245; H01L 2224/49175; H01L 2924/3862

(57) ABSTRACT

A semiconductor die is mounted on a substrate having electrically conductive substrate portions. The electrically conductive substrate portions include a die mounting location and electrically conductive leads around the die mounting location. The semiconductor die is mounted on a first surface of the die mounting location. The substrate and the semiconductor die are encapsulated in an electrically insulating encapsulation having a surface opposite the first surface. An electrically conductive path is provided to electrically couple the semiconductor die to one of the electrically conductive substrate portions. The electrically conductive path includes: a first path section extending through and/or over the electrically insulating encapsulation between the electrically conductive substrate portion and an intermediate point at the surface of the electrically insulating encapsulation, and a second path section provided via wire bonding and extending between the semiconductor die and the intermediate point at the surface of the electrically insulating encapsulation.

### PRIORITY CLAIM

This application claims the priority benefit of Italian Application for Patent No. 102023000014250 filed on Jul. 7, 2023, the content of which is hereby incorporated by reference in its entirety to the maximum extent allowable by law.

### TECHNICAL FIELD

The description relates to manufacturing semiconductor devices.

One or more embodiments may be applied to manufacturing integrated circuit (IC) semiconductor devices used, for instance, for automotive application.

### BACKGROUND

Semiconductor devices provided with a so-called quad flat package (QFP)—for automotive or industrial applications, for instance—may have a relatively high number of input/output (I/O) pins (or leads).

This is the case, for instance, of super high density (SHD) or super super high density (SSHD) devices that may have more than hundred pins.

In such leadframe based packages, a semiconductor chip/die is arranged on a die pad of the leadframe and electrically coupled to a plurality of leads provided around the die pad.

Wires are conventionally used to provide the desired couplings between the semiconductor die and the leads.

Wires may be used also for providing electrical couplings between the semiconductor die and the die pad, the die pad oftentimes being used to provide a ground level for the device.

With current processing techniques (such as stamping or etching) leads may be formed with a minimum pitch of about 150 microns to 180 microns; due to the relatively high number of leads and the reduced dimension of the package, the distance between the die pad and the proximal ends of the leads cannot be reduced beyond a minimum value, thus causing the wires coupling the die to the leads to be relatively long.

Longer wires have been observed to be more prone to issues related to the molding step; in fact, current manufacturing processes of semiconductor devices include a molding step where a resin or epoxy molding compound (EMC, an epoxy resin, for instance) is molded onto the device to form a protective plastic body. During the process, resin flow in the mold chase cavity may cause wire to “sweep”, that is, to deform in response to the viscous drag force exerted by the flowing molding compound.

Wire sweeping may exceed specification or, in worst cases, cause two neighboring wires to touch thus forming an undesired short circuit.

Moreover, it has been found that long wires tend to get damaged (collapse) more easily during processing (or just handling, for instance) of the devices.

Damaged or shorted wires may cause failure, and consequently rejection, of the device under processing, negatively affecting manufacturing yield and resulting in relatively low time- and cost-effectiveness of the manufacturing process.

There is a need in the art for embodiments which overcome the drawbacks discussed in the foregoing.

### SUMMARY

One or more embodiments relate to a method.

One or more embodiments relate to a corresponding semiconductor device.

Solutions as described herein facilitate reducing the length of wires that are used to electrically couple a semiconductor die to the leads or die pad.

In solutions as described herein a portion of the electrically conductive path providing a desired coupling is formed via deposition/growth of electrically conductive material (a metal such as copper, for instance).

Solutions as described herein may take advantage of laser direct structuring (LDS) to form a portion of the desired electrical coupling.

### BRIEF DESCRIPTION OF THE DRAWINGS

One or more embodiments will now be described, by way of example only, with reference to the annexed figures, wherein:

FIG. 1 is a plan view illustrative of the structure of a semiconductor device;

FIGS. 2A to 2F is a sequence of cross-sectional views illustrative of processing steps according to embodiments of the present description;

FIGS. 3A and 3B illustrate processing steps according to embodiments of the present description; and

FIGS. 4A and 4B are plan views illustrative of a coupling pattern in a semiconductor device according to a conventional approach and according to an embodiment of the present description, respectively.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments. The references used herein are provided merely for convenience and hence do not define the extent of protection or the scope of the embodiments.

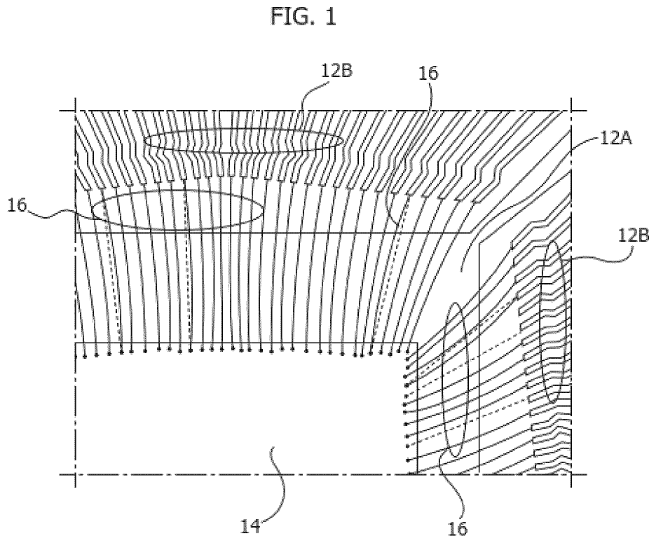

FIG. 1 is illustrative of a portion of an integrated circuit (IC) semiconductor device comprising a semiconductor chip or die 14 (as used herein, the terms chip/s and die/dice are regarded as synonymous) arranged on a mounting location 12A (die pad) of an electrically conductive substrate, conventionally referred to as leadframe.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

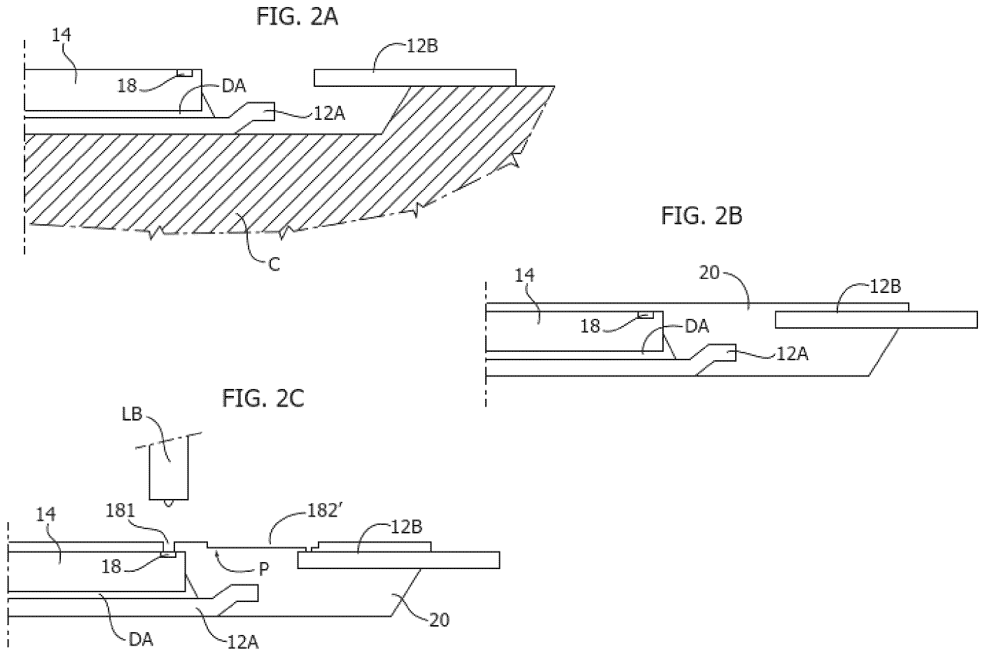

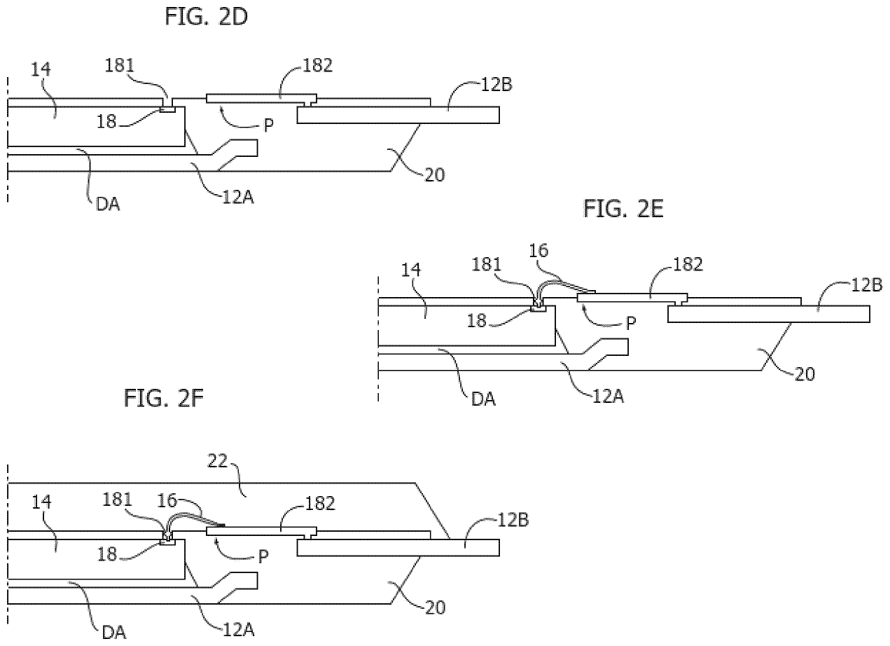

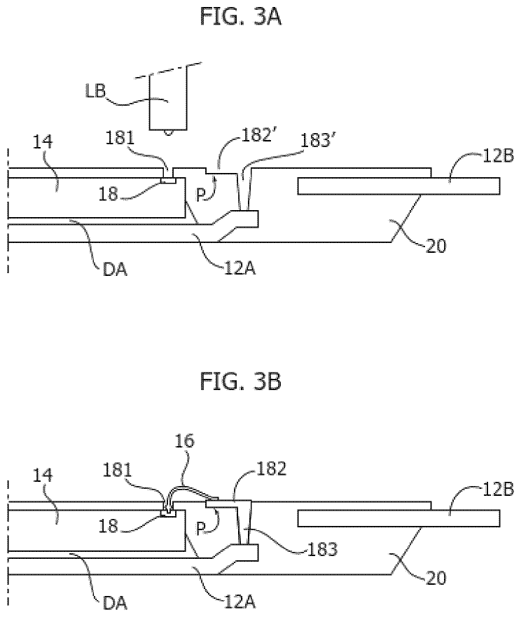

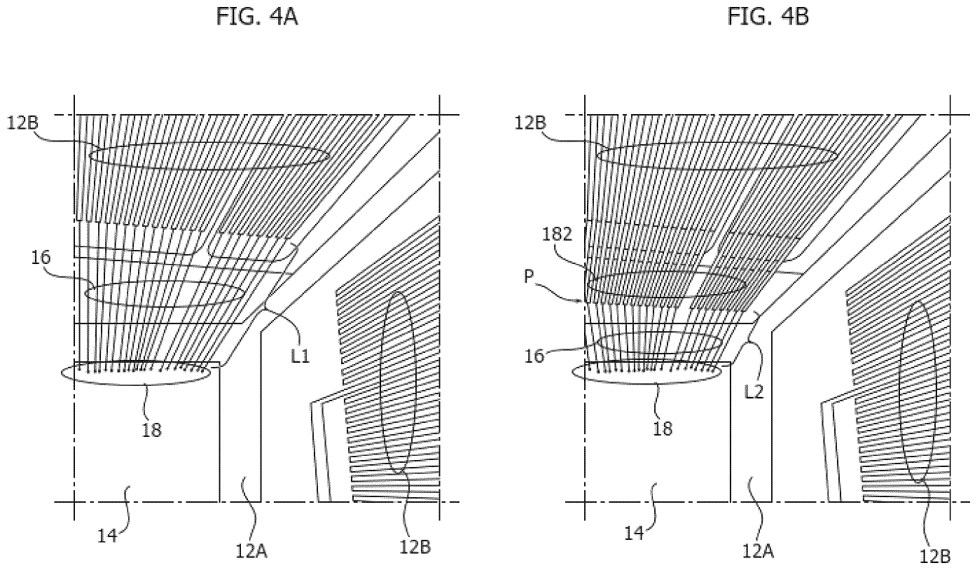

With reference to FIG. 1, a leadframe comprises an array of electrically-conductive formations or leads 12B that from an outline location extend inwardly in the direction of an (integrated circuit) semiconductor chip or die 14 thus forming an array of electrically-conductive formations from a die pad 12A configured to have at least one semiconductor chip or die 14 attached thereon. This may be via conventional means such as a die attach adhesive (a die attach film, for instance, as illustrated in FIGS. 2A to 2F and FIGS. 3A and 3B and referenced therein with the reference DA).

Electrically conductive formations are provided to electrically couple the semiconductor chip(s) to selected ones of the leads (outer pads) 12B in the leadframe.

As illustrated, such couplings can be provided via a wire-bonding pattern of wires 16, as conventional in the art.

After forming the electrical couplings between the chip 14 and the leads 12B, encapsulation material (e.g., an epoxy molding compound (EMC)) is molded onto the assembly thus formed to provide a protective plastic package to the device.

The molding step is conventionally performed by arranging the leadframe having the dice 14 mounted thereon in a molding cavity where the molding compound is injected at a relatively high pressure.

An integrated circuit semiconductor device as illustrated in FIG. 1 may have a relatively high number of input/output (I/O) leads 12B; for instance, devices such as microcontrollers or ASICs for automotive applications, provided with a quad flat package (QFP) as illustrated in the figures, may have more than hundred leads 12B.

The minimum pitch of leads 12B achievable with current techniques—about 150 to 180 microns depending on the technique used to form the leadframe and the leads 12B (etching or stamping, for instance)—may reduce flexibility of device design when a high number of leads 12B is desired, as it is the case in so-called super high density (SHD) or super super high density (SSHD) devices, for instance.

Due to minimum leads pitch, the distance between the leads 12B and the die pad 12A, cannot be reduced beyond a certain value: relatively long wires 16 are thus used to provide the desired electrical couplings between the semiconductor die 14 (mounted/attached on the die pad 12A) and the I/O leads 12B.

Long wires 16 have been observed to be more prone to deform (sweep) in response to the drag forces exerted by viscous flow of the molding compound during the molding step. Excessive sweep may cause rejection of the device and, in worst cases, may cause neighboring wires to touch thus forming an undesired short circuit that causes failure (and rejection) of a device.

FIG. 1 is illustrative of wire sweeping, namely undesired displacement of wires 16 resulting from a conventional molding process.

This effect is represented in the case of some exemplary wires 16 by representing the positions of the wires 16 before and after the molding process with dashed and solid lines, respectively.

Long wires have been found to be also more prone to be damaged or collapse during processing/handling of the devices.

Solutions as described herein aim at overcoming the drawbacks discussed in the foregoing.

Solutions as described herein may advantageously be applied to SHD or SSHD devices provided with a QFP type of package.

Solutions as described herein facilitate reducing wires length thus reducing sweeping and damaging thereof.

Solutions as described herein involve providing a first partial encapsulation and, subsequently, forming the desired electrical couplings.

In solutions as described herein a desired electrical coupling is provided by forming an electrically conductive path comprising two portions: a first portion provided via growth/deposition of electrically conductive material (a metal such as copper, for instance); and a second portion provided via wire bonding.

Solutions as described herein may take advantage of laser direct structuring (LDS) to form a portion of the desired electrical coupling.

Laser direct structuring (LDS) is a laser-based machining technique now widely used in various sectors of the industrial and consumer electronics markets, for instance for high-performance antenna integration, where an antenna design can be directly formed onto a molded plastic part.

In an exemplary process, the molded parts can be produced with commercially available insulating resins that include additives suitable for the LDS process; a broad range of resins such as polymer resins like PC, PC/ABS, ABS, LCP are currently available for that purpose.

In LDS, a laser beam can be used to transfer (“structure”) a desired electrically-conductive pattern onto a plastic molding that may then be subjected to metallization to finalize a desired conductive pattern.

Metallization may involve electroless plating followed by electrolytic plating.

Electroless plating, also known as chemical plating, is a class of industrial chemical processes that creates metal coatings on various materials by autocatalytic chemical reduction of metal cations in a liquid bath.

In electrolytic plating, an electric field between an anode and a workpiece, acting as a cathode, forces positively charged metal ions to move to the cathode where they give up their charge and deposit themselves as metal on the surface of the work piece.

Reference is made to United States Patent Application Publication Nos. 2018/0342453, 2019/0115287, 2020/0203264, 2020/0321274, 2021/0050226, 2021/0050299, 2021/0183748, or 2021/0305203 (all incorporated herein by reference) as exemplary of the possibility of applying LDS technology in manufacturing semiconductor devices.

The sequence of FIGS. 2A to 2F is illustrative of a sequence of processing steps providing the desired electrical couplings between a die 14 and the leads 12B.

It will be otherwise appreciated that the sequence of steps of FIGS. 2A to 2F is merely exemplary insofar as: one or more steps illustrated in FIGS. 2A to 2F can be at least partially omitted, performed in a different manner (with other tools, for instance) and/or replaced by other steps; additional steps may be added; and one or more steps can be carried out in a sequence different from the sequence illustrated.

FIG. 2A is illustrative of a leadframe of a quad flat package (QFP) device that is exemplary of a device where embodiments of the present description may advantageously be applied.

As illustrated, the die pad 12A may have a downset with respect to the array of electrically conductive leads 12B provided around the die pad 12A.

A semiconductor die 14 is arranged (attached via die attach material DA, for instance) on the top/front surface of the die pad 12A and has on the top/front surface thereof die bonding pads 18 (only one bonding pad is illustrated for simplicity) that are configured to be electrically coupled to a selected lead 12B or to the die pad 12A.

The assembly is arranged in a conventional mold cavity C in order to perform a first (partial) molding step.

For simplicity and ease of explanation, in the following description reference will be made to the manufacturing process of a single device being understood that, as known to those skilled in the art, plural devices may be concurrently processed and possibly separated into single individual devices in a final singulation step.

FIG. 2B is illustrative of an electrically insulating molding compound 20 (an epoxy resin, for instance) molded onto the leadframe (including the leads 12B) having a semiconductor die mounted thereon to provide a first, partial encapsulation of the device.

As illustrated, the semiconductor die 14 and the proximal portion of the leads 12B are embedded in the molding compound 20 while the bottom/back surface of the die pad 12A (configured to be mounted/soldered on a support such as a printed circuit board, PCB, for instance) and the distal portion of the leads 12B are left uncovered by the molding compound 20.

In certain embodiments the molding 20 compound used to form the first portion of the encapsulation may be a molding compound suitable for LDS; as mentioned, such a molding compound comprises additive particles that may be activated via laser beam energy to facilitate growth of metallic material.

FIG. 2C is illustrative of a laser machining step where laser beam energy LB is applied to the molding compound 20 to structure therein: vias 181 extending from the front/top surface of the partial encapsulation 20 to the die bonding pad 18 provided on the front/top surface of the semiconductor die 14; and traces 182′ extending at the front/top surface of the encapsulation 20 from the leads 12B to an intermediate location P between the leads 12B and the die 14.

As illustrated, laser ablation of the molding compound 20 to structure traces 182′ advantageously involves structuring further vias (visible and not expressly referenced in the figures for simplicity) at the distal end of the traces 182′ in order to expose metallic material (copper, for instance) of the leads 12B.

Those skilled in the art may appreciate that these further vias are optional since their presence depends on the thickness of the molding compound 20 and the relative heights of the leads 12B and the semiconductor die 14.

Traces 182′ are indicated by numbers with a prime designation (′) in order to highlight the fact that electrically conductive traces/lines 182 will be formed at those locations (only) after the subsequent metal growth as represented in FIG. 2D.

In the case an LDS molding compound has been used to form the first (partial) encapsulation 20, laser beam energy LB is applied to the LDS compound (that is, a molding compound having LDS additive added therein) to concurrently remove (ablate) the LDS compound 20 and “activate” the additive particles embedded in the LDS compound at the surface of the LDS compound exposed in response to a portion of LDS compound being removed (ablated) via laser.

FIG. 2D is illustrative of metallic material (copper, for instance) grown/deposited to form the electrically conductive traces 182.

Electrically conductive traces 182 may be formed via electrically conductive paste jetting or via laser induced forward transfer (LIFT), for instance.

The acronym LIFT denotes a deposition process where material from a donor tape or sheet is transferred to an acceptor substrate (here, the electrically insulating molding compound 20) facilitated by laser pulses.

General information on the LIFT process can be found, for instance, in P. Serra, et al.: “Laser-Induced Forward Transfer: Fundamentals and Applications”, in Advanced Materials Technologies/Volume 4, Issue 1 (incorporated herein by reference).

Advantageously, laser direct structuring technique may be used to provide traces 182.

In this case a first (“seed”) layer of metallic material (copper, for instance) is grown at locations of the molding compound 20 that have been activated via laser energy (that is, traces 182′) via electroless deposition.

The seed layer grown via electroless deposition facilitates growing (complete) traces 182 via electrolytic growth/deposition.

However formed, traces 182 provide a first portion (from the leads 12B to the intermediate point P) of an electrically conductive path from the lead 12B to the die bonding pad 18 on the top/front surface of the semiconductor die 14.

A plasma cleaning/etching step may follow the growing/deposition step illustrated in FIG. 2D.

FIG. 2E is illustrative of electrically conductive wires 16 provided to couple the die pad 18 to the proximal end of the electrically conductive trace 182, approximately at the intermediate point P. This process may be performed via any conventional method; for instance, conventional wire bonding may be used to provide the desired electrical couplings between the die pads 18 and the proximal ends of the traces 182.

As illustrated, wires 16 electrically coupling die bonding pads 18 to traces 182 provide a second portion of an electrically conductive path coupling the leads 12B to the semiconductor die 14.

FIG. 2F is illustrative of a second molding step that completes the protective plastic package of the device. A standard—that is, non-LDS—molding compound 22 may be used for this second molding step.

Shorter wires 16 electrically coupling the semiconductor die 14 to the intermediate point P (that is, the proximal end portion of the trace 182) experience a lower drag force and, consequently, less sweeping during the second molding step.

The processing steps described in the foregoing may be applied, in a similar way, also to provide electrical couplings between die bonding pads 18 and the die pad 12A (oftentimes providing the ground to the device).

FIGS. 3A and 3B illustrate processing steps according to embodiments of the present description providing a desired electrical coupling between semiconductor die 14 and die pad 12A.

FIG. 3A illustrates vias 181, 183′ opened through an insulating molding compound 20 molded onto a leadframe having a semiconductor die 14 mounted thereon to form a first (partial) encapsulation of the device.

Vias 181 and 183′ extend from the top/front surface of the first partial encapsulation to the die bonding pad 18 and the die pad 12A, respectively.

As illustrated, traces 182′ may also be formed at the top/front surface of the encapsulation 20 extending outwardly from an intermediate point P of the top/front surface of the encapsulation 20 to the end of the vias 183 at the surface of the first partial encapsulation 20.

Again, traces 182′ and vias 183′ are indicated by a prime designation (′) in order to highlight the fact that electrically conductive traces 182 and vias 183 will be formed at those locations (only) after the subsequent metal growth.

FIG. 3B is illustrative of an electrically conductive path provided to electrically couple the die bonding pad 18 on the top/front surface of the semiconductor die 14 to the die pad 12A.

Similarly to the case discussed in the foregoing (in relation to FIG. 2E, for instance), the electrically conductive path comprises two portions/sections, namely: a first section 182, 183, extending from the die pad 12A to an intermediate point P the surface of the encapsulation 20, formed via deposition/growth of electrically conductive material (a metal such as copper, for instance); and a second section from the die bonding pad 18 to the intermediate point P, provided via wire bonding.

As illustrated, the first portion of the electrically conductive path may comprise a via 183 extending through the molding compound of the partial encapsulation 20 and a trace 182 formed at the surface of the encapsulation 20.

Also in this case, the LDS technique may advantageously be used to form the first portion of the electrically conductive path, namely electrically conductive vias 183 and traces 182.

Processing as described in the foregoing to provide electrical couplings between die bonding pads 18 and die pad 12A results in relatively short wires 16 that are less exposed to issues during molding step (sweeping) and/or handling (collapsing).

It is noted that the processing steps illustrated in FIGS. 2A to 2F—to electrically couple a semiconductor die 14 to leads 12B—and those illustrated in FIGS. 3A and 3B—to electrically couple a semiconductor die 14 to a die pad 12A—may be applied in a same device.

In fact, some of the die bonding pads 18 of the semiconductor die 14 may be configured to be electrically coupled to selected ones of the leads 12B, while others may be configured to be electrically coupled to the die pad 12A (providing the ground level, for instance).

To summarize, solutions described herein involve mounting a semiconductor die 14 on a substrate (that is, a leadframe) having electrically conductive substrate portions that comprise a die mounting location (a die pad) 12A and a plurality of electrically conductive leads 12B around the die mounting location 12A. The semiconductor die 14 is mounted on a first (top/front) surface of the die mounting location 12A.

The substrate having the semiconductor die 14 mounted thereon is encapsulated in an electrically insulating encapsulation 20. The electrically insulating encapsulation 20 has a (top/front) surface opposite the first surface of the die mounting location 12A.

One or more electrically conductive paths are provided to electrically couple the semiconductor die 14 to one of the electrically conductive substrate portions (a lead 12B or the die pad 12A, for instance).

The electrically conductive paths comprise: a first path section 182,183 extending through and/or over the electrically insulating encapsulation 20 between the electrically conductive substrate portion (a lead 12B or the die pad 12A) and an intermediate point P at the surface of the electrically insulating encapsulation 20; and a second path section provided via wire 16 bonding and extending between the semiconductor die 14 and the intermediate point P at the surface of the first encapsulation 22.

The first section of the electrically conductive path mat be provided via deposition/growth of electrically conductive material (a metal such as copper, for instance).

Advantageously, the first section of the electrically conductive path may be provided via LDS technique, involving, for instance: molding LDS suitable molding compound to form the first (partial) encapsulation 20 of the substrate having a semiconductor die 14 mounted thereon; transferring the desired pattern to the first encapsulation via laser structuring (ablating the LDS molding compound and activating the additive particles embedded therein) to form vias 181,183′ and traces 182′; and metallizing vias 183 and traces 182 previously activated to provide the first portion of the electrically conductive path.

FIGS. 4A and 4B are exemplary of a QFP device (SHD or SSHD, for instance) where the desired electrical couplings (only from the semiconductor die 14 to the leads 12B, for simplicity) are provided according to a conventional approach (FIG. 4A) and according to an embodiment of the present description (FIG. 4B).

As illustrated in FIG. 4A, wires 16 extending between a die bonding pad 18 on the top/front surface of the semiconductor die 14 and the lead 12B have a first, relatively large, length L1 (on average).

In contrast, wires 16 as illustrated in FIG. 4B, providing only a portion of the desired electrical couplings between the semiconductor die 14 and the leads, that is, extending only to the intermediate point P on the surface of the first, partial encapsulation (not visible in FIGS. 4A and 4B for simplicity), have (on average) a second length L2 less than L1.

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A method, comprising:
mounting a semiconductor die on a substrate having electrically conductive substrate portions, wherein the electrically conductive substrate portions comprise a die mounting location and a plurality of electrically conductive leads around the die mounting location, wherein the semiconductor die is mounted on a first surface of the die mounting location;
encapsulating both the semiconductor die and the substrate in a first electrically insulating encapsulation, wherein the first electrically insulating encapsulation has a surface opposite the first surface of the die mounting location;
providing an opening in the surface of the first electrically insulating encapsulation to expose a die bonding pad of the semiconductor die;
providing an electrically conductive path section extending through and on the first electrically insulating encapsulation between an electrically conductive lead and an intermediate point at the surface of the first electrically insulating encapsulation;
providing a wire bonding in said opening in the surface of the first electrically insulating encapsulation and extending between the die bonding pad of the semiconductor die and the electrically conductive path section at said intermediate point.

2. The method of claim 1, further comprising encapsulating the electrically conductive path section and the wire bonding in a second electrically insulating encapsulation.

3. The method of claim 1, wherein the die mounting location has a downset with respect to the plurality of electrically conductive leads around the die mounting location.

4. The method of claim 1, wherein the first electrically insulating encapsulation comprises a laser direct structuring (LDS) molding compound.

5. The method of claim 4, wherein providing the electrically conductive path section comprises:
LDS processing said LDS molding compound to form a trace and a via opening; and
forming electrically conductive structures at said trace and via opening.

6. The method of claim 1, further comprising:
providing a further opening in the first electrically insulating encapsulation to expose a further die bonding pad of the semiconductor die;
providing a further electrically conductive path section extending through and on the first electrically insulating encapsulation between the substrate and a further intermediate point at the surface of the first electrically insulating encapsulation; and
providing a further wire bonding in said further opening and extending between the further die bonding pad of the semiconductor die and the further electrically conductive path section at said further intermediate point.

7. The method of claim 6, further comprising encapsulating the electrically conductive path section, the further electrically conductive path section, the wire bonding and the further wire bonding in a second electrically insulating encapsulation.

8. The method of claim 6, wherein the die mounting location has a downset with respect to the plurality of electrically conductive leads around the die mounting location.

9. The method of claim 6, wherein the first electrically insulating encapsulation comprises a laser direct structuring (LDS) molding compound.

10. The method of claim 9, wherein providing the further electrically conductive path section comprises:
LDS processing said LDS molding compound to form a trace and a via opening; and
forming electrically conductive structures at said trace and via opening.

11. A device, comprising:
a substrate having electrically conductive substrate portions, wherein the electrically conductive substrate portions comprise a die mounting location and a plurality of electrically conductive leads around the die mounting location;
a semiconductor die mounted on a first surface of the die mounting location of the substrate;
a first electrically insulating encapsulation which encapsulates both the substrate and the semiconductor die, wherein the first electrically insulating encapsulation has a surface opposite the first surface of the die mounting location;
an opening in the first electrically insulating encapsulation exposing a die bonding pad of the semiconductor die;
an electrically conductive path section extending through and on the first electrically insulating encapsulation between an electrically conductive lead and an intermediate point at the surface of the first electrically insulating encapsulation; and
a wire bonding in said opening in the first electrically insulating encapsulation and extending between the die bonding pad of the semiconductor die and the electrically conductive path section at said intermediate point.

12. The device of claim 11, further comprising a second electrically insulating encapsulation which encapsulates the electrically conductive path section and the wire bonding.

13. The device of claim 11, wherein the die mounting location has a downset with respect to the plurality of electrically conductive leads around the die mounting location.

14. The device of claim 11, wherein the first electrically insulating encapsulation comprises a laser direct structuring (LDS) molding compound.

15. The device of claim 14, wherein the electrically conductive path section comprises:
a trace and a via opening formed by LDS processing in said LDS molding compound; and
electrically conductive structures at said trace and via opening.

16. The device of claim 11, further comprising:
a further opening in the first electrically insulating encapsulation exposing a further die bonding pad of the semiconductor die;
a further electrically conductive path section extending through and/or over the first electrically insulating encapsulation between the substrate and a further intermediate point at the surface of the first electrically insulating encapsulation; and
a further wire bonding in said further opening and extending between the further die bonding pad of the semiconductor die and the further electrically conductive path section at said further intermediate point.

17. The device of claim 16, further comprising a second electrically insulating encapsulation which encapsulates the electrically conductive path section, the further electrically conductive path section, the wire bonding and the further wire bonding.

18. The device of claim 16, wherein the die mounting location has a downset with respect to the plurality of electrically conductive leads around the die mounting location.

19. The device of claim 16, wherein the first electrically insulating encapsulation comprises a laser direct structuring (LDS) molding compound.

20. The method of claim 19, wherein the further electrically conductive path section comprises:
a trace and a via opening formed by LDS processing in said LDS molding compound; and
electrically conductive structures at said trace and via opening.
